(19) United States
(12) Patent Application Publication
(10) Pub. No.: US 2006/0289891 A1
(43) Pub. Date: Dec. 28, 2006

(54) Electronic and/or optoelectronic devices grown on free-standing GaN substrates with GaN spacer structures

(76) Inventor: Edward Lloyd Hutchins, Raleigh, NC (US)

Correspondence Address: INTELLECTUAL PROPERTY / TECHNOLOGY LAW, PO BOX 14329, RESEARCH TRIANGLE PARK, NC, 27709, US

(21) Appl. No.: 11/168,501

(22) Filed: Jun. 28, 2005

(51) Int. Cl. H01L 33/00

(52) U.S. Cl. 257/103

(57) ABSTRACT

A GaN-based electronic and/or optoelectronic device formed on a free-standing GaN substrate, wherein a thick GaN spacer layer is provided between the device and the substrate, thereby separating the active region of the electronic and/or optoelectronic device from high impurity content at the substrate-epitaxial interface and reducing the detrimental impact of such interfacial impurity on the performance of the electronic and/or optoelectronic device. The GaN spacer layer has a thickness of at least about 0.5 microns, and preferably from about 0.5 micron to about 2 microns.

### BACKGROUND OF THE INVENTION

1. Field of the Invention

This invention relates generally to GaN-based electronic or optoelectronic devices, including but not limited to diodes, transistors, and lasers.

2. Description of the Related Art

Compound semiconductors far exceed the physical properties of silicon, and GaN-based materials are the most dynamic of all the III-V materials. As a result, the capabilities—such as amplifying (without distorting) high-frequency RF signals, withstanding high temperatures, emitting blue and green light—make GaN-based materials ideally suited for a wide range of electronic and optoelectronic applications, such as diodes, transistors, and lasers.

For example, high electron mobility transistors (HEMTs) based on GaN/AlGaN heterostructures are well suited for high power microwave amplifiers encompassing the 2-40 GHz frequency range. The advantages of GaN-based materials over Si and GaAs in forming HEMT structures derive from their wide bandgap, high breakdown field and high electron saturation velocity characteristics, which impart to GaN-based materials the potential to surpass existing device limitations in output power, operating voltage and operating temperature.

In recent years, GaN-based light-emitting diodes (LEDs) emitting in the spectral window of green to UV have extended their range of applications, to include traffic signals, display and automotive applications, and environmental protection as well as general lighting. The key advantages of these GaN-based solid state light sources are lower energy consumption, long device lifetime and mechanical robustness.

Further, since the first demonstration of GaN-based blue laser diodes in the 1990's, the development of blue/violet laser devices using GaN-based materials has achieved significant success. Short wavelength GaN-based diode lasers have a variety of applications, including high density optical data storage (DVD-RAM/Blue Ray Disk), laser printing, spectroscopy, sensing and projection displays.

Most GaN-based electronic and optoelectronic devices have been manufactured in the past by heteroepitaxial deposition of GaN-based layers on substrates such as sapphire or silicon carbide, because high-quality homoepitaxial GaN substrates were unavailable.

In such prior heteroepitaxial fabrication, the lattice mismatch between the GaN-based epitaxial layer and the heteroepitaxial substrate causes high dislocation density in the GaN-based device structure, which in turn significantly reduces the service life of the resulting GaN-based device products. In order to accommodate the lattice mismatch between the GaN-based epitaxial layer and the substrate and to reduce dislocation density in the epitaxial layer, a thick AlN or GaN buffer layer, typically on the order of 2-4 microns in thickness, is provided between the epitaxial layer and the substrate. Such thick AlN or GaN buffer layer functions to separate the epitaxial layer from the heteroepitaxial substrate, thereby providing an intervening distance in the structure over which the dislocations can annihilate one another.

Free-standing GaN substrates have recently become available for homoepitaxial growth of GaN-based device structures, and such substrates significantly reduce or eliminate the problem of lattice mismatch dislocations typically associated with the use of heteroepitaxial substrates.

With respect to specific growth techniques, pseudo-bulk and bulk GaN have been successfully grown by hydride/halide vapor phase epitaxy (HVPE). In an illustrative process, HCl is reacted with liquid Ga to form vapor-phase GaCl, which then is transported to a substrate where it reacts with injected NH₃ to form GaN. Typically, the deposition is performed on a non-GaN substrate such as sapphire, silicon, gallium arsenide, or LiGaO₂, which can be removed, either subsequently or in situ, to form a free-standing GaN article that can then be used as a homoepitaxial substrate for GaN-based device structures. For example, Vaudo et al. U.S. Pat. No. 6,596,079 describes a method of fabricating free-standing GaN wafers or boule with a dislocation density below 10⁷ cm⁻². Further, Yasan and co-workers describe formation of a homoepitaxial ultraviolet light-emitting diode with peak emission at 340 nm grown on a free-standing HVPE GaN substrate. See A. Yasan et al., Comparison of Ultraviolet Light-Emitting Diodes with Peak Emission at 340 nm Grown on GaN Substrate and Sapphire, APPLIED PHYSICS LETTERS, Vol. 81, No. 12 (Sep. 16, 2002).

There is a continuing need in the art for improving the quality and performance of GaN-based electronic and optoelectronic devices that are formed on free-standing GaN substrates.

### SUMMARY OF THE INVENTION

The present invention relates to GaN-based electronic and optoelectronic devices formed on free-standing GaN substrates.

In one aspect, the invention relates to an electronic or optoelectronic assembly, which includes:
a free-standing GaN substrate including doped or undoped GaN material;
a spacer layer formed on the free-standing GaN substrate, wherein the spacer layer includes doped or undoped GaN material and has a thickness in a range of from about 0.5 microns to about 2 microns; and
an electronic or optoelectronic device structure formed on the spacer layer, wherein the electronic or optoelectronic device structure includes GaN-based material layers.

Electronic or optoelectronic device structures that can be formed on the substrate/spacer structure described above include, but are not limited to, light-emitting diodes (LEDs), laser diodes (LDs), metal semiconductor field-effect transistors (MESFETs), power transistors, ultraviolet photodetectors, pressure sensors, temperature sensors, and surface acoustic wave devices, as well as other electronic and/or optoelectronic devices that can be advantageously fabricated on conductive substrates and/or spacer layers of such type.

In another aspect, the invention relates to a light-emitting diode assembly, including:
a free-standing GaN substrate including doped or undoped GaN material;
a spacer layer formed on the free-standing GaN substrate, wherein the spacer layer includes doped or undoped GaN material and has a thickness in a range of from about 0.5 microns to about 2 microns; and
a GaN-based light-emitting diode structure formed on the spacer layer, the light-emitting diode structure including: (1) one or more lower carrier confinement layers, (2) one or more upper carrier confinement layers, and (3) one or more light-emitting active layers formed between the lower and upper carrier confinement layers, wherein the lower and upper carrier layers respectively include GaN-based materials doped with opposite types of dopant species and are in electrical contact with opposite electrodes, and wherein the one or more light-emitting active layers include undoped GaN-based materials.

Such GaN-based light-emitting diode structure may be a constituent structure of a UV LED, a blue LED, or a green LED.

The term “gallium nitride” or “GaN” as used herein refers to either doped (n-type or p-type) or undoped gallium nitride that is substantially free of other impurities besides the dopant species.

The term “gallium-nitride-based” or “GaN-based” as used herein refers inclusively and alternatively to materials that contain either gallium nitride or a composite gallium nitride that further contains Al and/or In, thereby alternatively encompassing each of GaN, AlₓGa₁₋ₓN (or AlGaN), In_{y}Ga_{1-y}N (or InGaN), or AlₓIn_{y}Ga_{1-x-y}N (or AlInGaN) materials, wherein 0<x<1 and 0<y<1, as well as mixtures thereof and doped materials (n-type or p-type) or undoped materials.

The term “(Al,In,Ga)N” as used herein refers inclusively and alternatively to each of individual nitrides containing one or more of Al, In and Ga, thereby alternatively encompassing each of GaN, AlN, AlₓIn₁₋ₓN (or AlInN), AlₓGa₁₋ₓN (or AlGaN), InN, In_{y}Ga_{1-y}N (or InGaN), and AlₓIn_{y}Ga_{1-x-y}N (or AlInGaN) materials, where 0≦x≦1 and 0≦y≦1, as well as mixtures thereof and doped materials (n-type or p-type) or undoped materials.

Other aspects, features and embodiments of the invention will be more fully apparent from the ensuing description and claims.

### BRIEF DESCRIPTION OF THE DRAWINGS

FIG. 1 is an illustrative view of an exemplary electronic or optoelectronic assembly, according to one embodiment of the present invention.

FIG. 2 is an illustrative view of a light-emitting diode assembly, according to one embodiment of the present invention.

FIG. 3A is a graph of photoluminescence intensity plotted as a function of wavelength, in nanometers, for an ultraviolet light emitting diode (UVLED) formed directly on an n-type freestanding GaN substrate.

FIG. 3B is a graph of photoluminescence intensity plotted as a function of wavelength, in nanometers, for a UVLED formed on an n-type freestanding GaN substrate having a thin GaN spacer layer with a thickness of about 0.1 micron thereon.

FIG. 3C is a graph of photoluminescence intensity plotted as a function of wavelength, in nanometers, for a UVLED formed on an n-type freestanding GaN substrate having a thick GaN spacer layer of about 0.5 microns thickness thereon.

FIG. 3D is a graph of photoluminescence intensity plotted as a function of wavelength, in nanometers, for a UVLED formed on an n-type freestanding GaN substrate having a thick GaN spacer layer of about 0.5 microns thickness thereon, in which the UVLED further includes an AlN barrier layer between p-type upper carrier confinement layers and the light-emitting active layers.

FIG. 4 is a secondary ion mass spectrometry (SIMS) plot, showing the high impurity content at the interface between a free-standing GaN substrate and an epitaxial layer grown thereon.

### DETAILED DESCRIPTION AND PREFERRED EMBODIMENTS OF THE INVENTION

The present invention relates to improved GaN-based electronic and/or optoelectronic devices grown on free-standing GaN homoepitaxial substrates.

The use of free-standing GaN homoepitaxial substrates significantly reduces or eliminates the problem of lattice mismatch dislocations associated with previously employed heteroepitaxial substrates, such as sapphire and SiC, with which thick AlN or GaN buffer layers are used to accommodate lattice mismatch. Such thick AlN or GaN buffer layers are not needed in the fabrication of GaN-based electronic and/or optoelectronic devices grown on free-standing GaN homoepitaxial substrates.

The present inventor has, however, observed significant limitations of performance of homoepitaxially grown electronic and/or optoelectronic devices, which are overcome by the present invention.

The present inventor has studied the optical efficiency of GaN-based ultraviolet light-emitting diodes (UVLEDs), by temperature-dependent photoluminescence studies of the UV active regions of such devices. For UVLEDs containing GaN/AlGaN quantum well structures, photoluminescent intensity peaks for both GaN and AlGaN are expected to be observed. However, the present inventor observed that GaN-based ultraviolet light-emitting diodes formed directly on free-standing GaN substrates, contrary to expectation, showed no significant photoluminescent intensity peak from the UV active region.

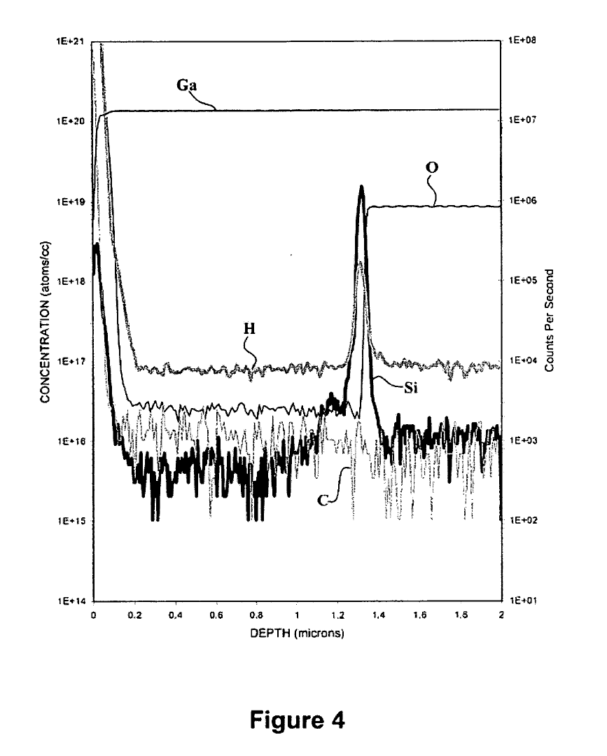

Upon further study, is the present inventor discovered that this problem is attributable to a high impurity content at the interface between the free-standing GaN homoepitaxial substrate and the epitaxial device structure grown thereon. For example, FIG. 4 shows a secondary ion mass spectrometry (SIMS) plot for a layer of epitaxial GaN grown directly on a free-standing GaN homoepitaxial substrate, demonstrating high silicon and hydrogen impurity content at the substrate/epitaxy interfacial region.

The present invention provides a very simple and effective solution to such interfacial impurity problem, by deploying a GaN spacer layer between the free-standing GaN substrate and the UVLED or other electronic/optoelectronic device formed on such free-standing GaN substrate, thereby separating the high-impurity substrate/epitaxial interfacial region and the active regions of the electronic/optoelectronic device and reducing the impact of the interfacial impurity content on the performance of such electronic/optoelectronic device. The spacer layer thereby functions to remove the active region of the UVLED or other electronic/optoelectronic device from the region of high interfacial impurities. The spacer layer does not degrade crystal quality since it is formed on the template of the existing material of the GaN substrate.

Such GaN spacer layer consists essentially of doped or undoped GaN material. It is important that the GaN spacer layer has a sufficient thickness, suitably at least about 0.5 micron, e.g., in a range from about 0.5 micron to about 2 microns, so that the active regions of the electronic/optoelectronic device are separated by a sufficient distance in order to significantly reduce or minimize the impact of the interfacial impurity content on the performance of such electronic/optoelectronic device. On the other hand, a GaN spacer layer that is too thick (>2 microns) may result in an unfavorable surface feature that will impair the device performance. In various embodiments of the invention, the GaN spacer layer has a thickness in a range of from 0.5 micron to 2 microns, and another embodiments, the thickness of the GaN spacer layer can be in a range of from 0.5 to 1.5 μm, or in a range of from 0.5 to 1.0 μm, or in a range of from 1.0 to 1.5 μm, as necessary and/or desirable in a given implementation of the GaN structure of the invention.

The spacer layer desirably has a conductivity that is comparable to that of the free-standing GaN substrate, and a composition that is different from the composition of the free-standing GaN substrate. For example, when the free-standing GaN substrate is doped with an n-type dopant species such as oxygen, the spacer layer can doped with an n-type dopant species such as silicon.

More preferably, the free-standing GaN substrate is an n-type conductive substrate, and the spacer layer comprises an n-type GaN material with a dopant concentration between 2×10¹⁷ atoms/cc and 5×10¹⁸ atoms/cc, and most preferably such spacer layer has a dopant concentration of in the vicinity of 1×10¹⁸ atoms/cc.

Such substrate/spacer structure can be used to form various GaN-based electronic or optoelectronic devices, such as light-emitting diodes (LEDs), laser diodes (LDs), metal semiconductor field-effect transistors (MESFETs), power transistors, ultraviolet photodetectors, pressure sensors, temperature sensors, and surface acoustics wave devices.

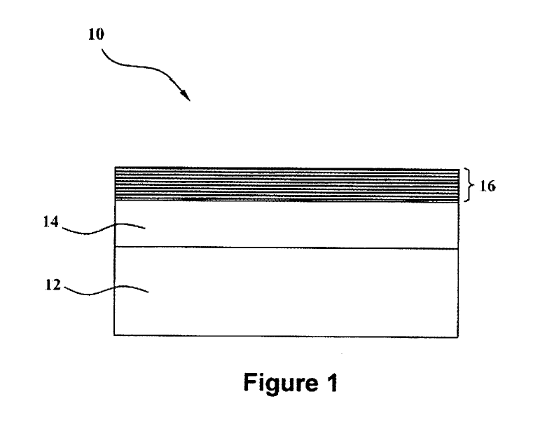

FIG. 1 illustratively shows an exemplary electronic or optoelectronic assembly 10 comprising a substrate/spacer structure as described hereinabove. Specifically, the electronic or optoelectronic assembly 10 comprises a free-standing GaN substrate 12 formed essentially of doped or undoped GaN material, a spacer layer 14 formed over the substrate 12 and consisting essentially of doped or undoped GaN material having a conductivity substantially similar to that of substrate 12, and a GaN-based electronic or optoelectronic device 16 formed over the spacer layer 14.

In a preferred embodiment of the present invention, a GaN-based light-emitting diode is formed over the substrate/spacer structure of the present invention.

The essential components of such GaN-based light-emitting diode (LED) include a light-emitting active region that is sandwiched between upper and lower carrier confinement regions of opposite conductivity, defining a p-n junction. For example, such LED may comprise one or more lower carrier confinement layers that comprise n-doped (or, alternatively, p-doped) GaN-based materials in electrical contact with an n-electrode (or, alternatively, a p-electrode), one or more upper carrier confinement layers that comprise p-doped (or, alternatively, n-doped) GaN-based materials in electrical contact with a p-electrode (or, alternatively, an n-electrode), and one or more light-emitting active layers between such upper and lower carrier confinement layers.

The active regions of such GaN-based LED may comprise single or multiple quantum wells formed by alternating GaN-based material layers of different composition. Such GaN-based LED may further comprise one or more optional structural layers, such as a p-doped GaN contact layer, p-doped and/or n-doped cladding layers, p-doped and/or n-doped light-guiding layers, p-doped and/or n-doped blocking layers, and/or one or more passivation layers, as known in the field of GaN-based light-emitting devices and readily implementable by those ordinarily skilled in the art.

In one embodiment of the present invention, the n-electrode and p-electrode of such GaN-based LED are in direct electrical contact with the upper and lower carrier confinement layers, respectively, and the free-standing GaN substrate and the GaN spacer layer are both undoped.

In an alternative embodiment of the present invention, the free-standing GaN substrate and the GaN spacer layer are doped with either n-type or a p-type dopant species, and the substrate is in contact with either the n-electrode or the p-electrode. Such arrangement allows indirect electric contact of the lower carrier confinement layers with the n- or p-electrode through backside contact.

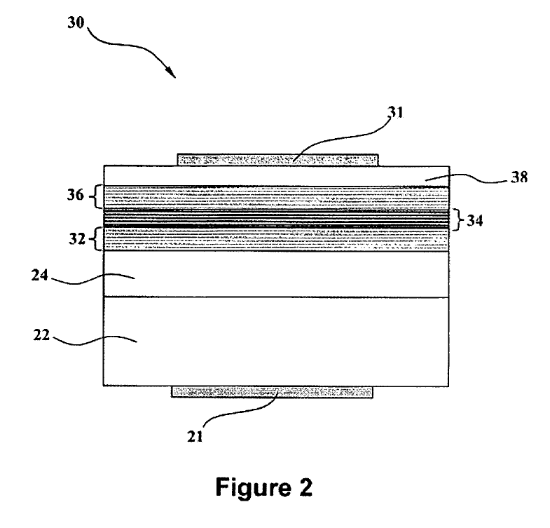

FIG. 2 illustratively shows an exemplary GaN-based light-emitting diode assembly 30 that includes a free-standing n-type GaN substrate 22, an n-doped GaN spacer layer 24, and a GaN-based light-emitting diode composed of one or more n-doped GaN-based lower carrier confinement layers 32, one or more undoped GaN-based light-emitting active layers 34, one or more p-doped GaN-based upper carrier confinement layers 36, a p-doped GaN contact layer 38, n-electrode 21 and p-electrode 31. Since both the substrate 22 and the spacer layer 24 are n-doped, they provide a backside n-contact 21 therethrough.

The LED assembly shown in FIG. 2 is provided for illustrative purposes only and should not be construed to limit the broad scope of the present invention in any manner.

The incorporation of a sufficiently thick GaN spacer layer between the free-standing n-type GaN substrate and the GaN-based LED device was determined to significantly improve the optical performance of such LED device.

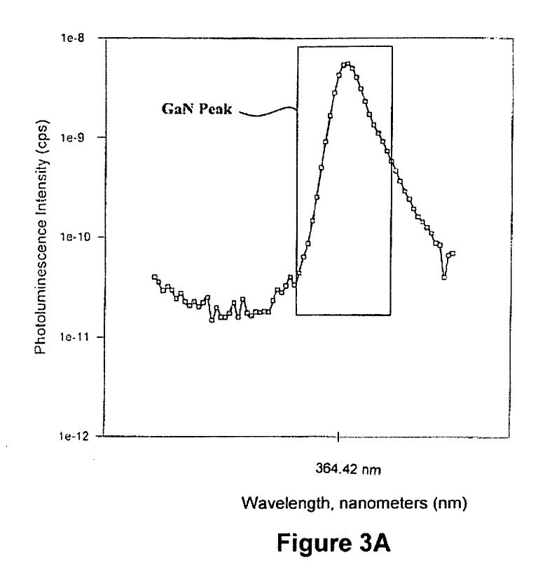

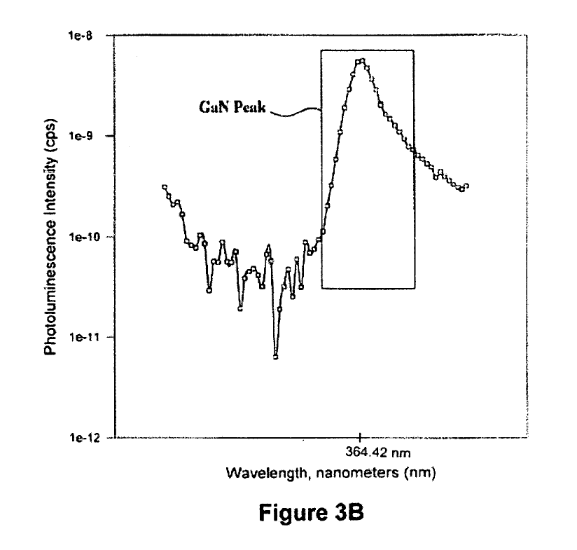

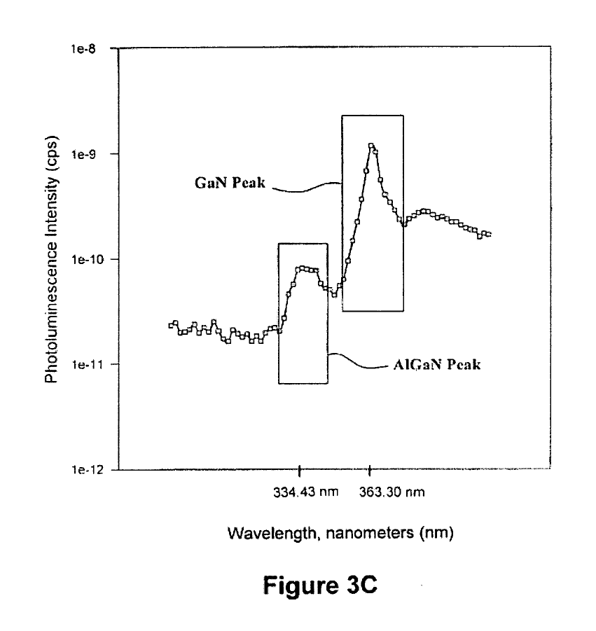

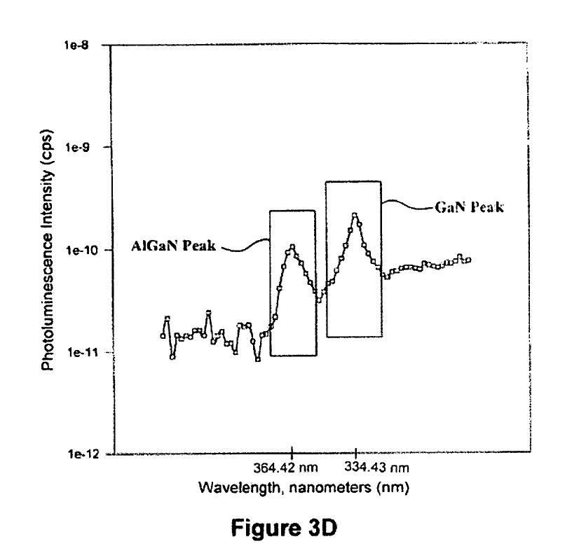

For example, FIGS. 3A-3D show the photoluminescent study results of four different UVLED assemblies. The UVLED assembly in all cases is fabricated on a free-standing GaN substrate. The UVLED assembly itself incorporates an Al(x)Ga(1-x)N/Al(y)Ga(1-y)N multiple quantum well (MQW) structure in which x>y, y>0, and y is chosen such that the expected photoluminescence of the MQW structure is about 340 nm.

FIG. 3A shows the photoluminescent intensity of the UVLED, formed directly over a free-standing GaN substrate, plotted as a function of wavelength, in nanometers. The photoluminescent intensity plot of FIG. 3A shows a GaN peak at about 364.42 nm, but no observable AlGaN peak is present. FIG. 3B shows the photoluminescent intensity plot of a UVLED formed over a free-standing GaN substrate and a thin GaN spacer layer (approximately 0.1 micron in thickness), which shows a GaN peak at about 364.42 nm and which also lacks an observable AlGaN peak. FIG. 3C shows a photoluminescent intensity plot of a UVLED formed over a free-standing GaN substrate and a thick GaN spacer layer (approximately 0.5 micron in thickness), which exhibits both a GaN peak at about 363.30 nm and an AlGaN peak at about 334.43 nm. FIG. 3D shows a photoluminescent intensity plot of a UVLED formed over a substrate/spacer structure similar to that of FIG. 3C, in which the UVLED further includes an AlN barrier structure between the p-type upper carrier confinement layers and the light-emitting active layers. Such AlN barrier structure functions to prevent detrimental diffusion of p-type dopant species (such as Mg) into active regions, as described more fully in U.S. Patent Application Publication No. 2004/0222431 A1 published on Nov. 11, 2004 for “III-Nitride Optoelectronic Device Structure with High Al AlGaN Diffusion Barrier,” the content of which is incorporated by reference herein in its entirety. The photoluminescent intensity plot of FIG. 3D also shows both a GaN peak at about 364.42 nm and an AlGaN peak at about 334.43 nm.

In FIGS. 3A and 3B, photoluminescence peaks are present in the vicinity of 364 nm. These peaks are attributable to the free-standing GaN substrate, and not to any MQW structure. Only when the AlₓGa₁₋ₓN/Al_{y}Ga_{1-y}N MQW structure is sufficiently removed from the high-impurity interfacial region, by a sufficiently thick spacer layer, is the desired photoluminescence from the MQW possible (FIGS. 3C and 3D).

Although the invention has been described herein primarily in reference to LED structures, it will be appreciated that the invention also is broadly applicable to other electronic and/or optoelectronic devices, e.g., laser diodes (LDs), metal semiconductor field-effect transistors (MESFETs), power transistors, ultraviolet photodetectors, pressure sensors, temperature sensors, surface acoustic wave devices, and other devices that are advantageously fabricated on a conductive substrate and/or spacer layer in accordance with the invention.

While the invention has been described herein with reference to specific aspects, features and embodiments, it will be recognized that the invention is not thus limited, but rather extends to and encompasses other variations, modifications and alternative embodiments. Accordingly, the invention is intended to be broadly interpreted and construed to encompass all such other variations, modifications, and alternative embodiments, as being within the scope and spirit of the invention as hereinafter claimed.

What is claimed is:

1. An electronic and/or optoelectronic assembly, comprising:
a free-standing GaN substrate comprising doped or undoped GaN material;
a spacer layer formed on said free-standing GaN substrate, wherein said spacer layer comprises doped or undoped GaN material and has a thickness in a range of from about 0.5 microns to about 2 microns; and
an electronic and/or optoelectronic device structure formed on said spacer layer, wherein said electronic and/or optoelectronic device structure comprises GaN-based material layers.

2. The electronic and/or optoelectronic assembly of claim 1, wherein the electronic and/or optoelectronic device structure is selected from the group consisting of diodes, transistors, and lasers.

3. The electronic and/or optoelectronic assembly of claim 1, wherein the electronic and/or optoelectronic device structure is selected from the group consisting of light-emitting diodes (LEDs), laser diodes (LDs), metal semiconductor field-effect transistors (MESFETs), power transistors, ultraviolet photodetectors, pressure sensors, temperature sensors, and surface acoustic wave devices.

4. The electronic and/or optoelectronic assembly of claim 1, wherein both the free-standing GaN substrate and the spacer layer are doped with n-type dopant species.

5. The electronic and/or optoelectronic assembly of claim 1, wherein both the free-standing GaN substrate and the spacer layer are doped with p-type dopant species.

6. The electronic and/or optoelectronic assembly of claim 1, wherein conductivity of the spacer layer is substantially similar to that of the free-standing GaN substrate.

7. The electronic and/or optoelectronic assembly of claim 6, wherein the spacer layer and the free-standing GaN substrate define an interfacial region therebetween, which has a high impurity concentration in relation to remaining regions of said spacer layer and said GaN substrate.

8. The electronic and/or optoelectronic assembly of claim 1, wherein the spacer layer is doped with an n-type dopant species at a concentration ranging from about 2×10¹⁷ to about 5×10¹⁸ atoms/cc.

9. The electronic and/or optoelectronic assembly of claim 1, wherein the spacer layer has a thickness in a range of from 0.5 μm to 2.0 μm.

10. The electronic and/or optoelectronic assembly of claim 1, wherein the spacer layer has a thickness in a range of from 0.5 μm to 1.5 μm.

11. The electronic and/or optoelectronic assembly of claim 1, wherein the spacer layer has a thickness in a range of from 0.5 μm to 1.0 μm.

12. The electronic and/or optoelectronic assembly of claim 1, wherein the spacer layer has a thickness in a range of from 1.0 μm to 1.5 μm.

13. A light-emitting diode assembly, comprising:
a free-standing GaN substrate comprising doped or undoped GaN material;
a spacer layer formed on said free-standing GaN substrate, wherein said spacer layer comprises doped or undoped GaN material and has a thickness in a range of from about 0.5 micron to about 2 microns; and
a GaN-based light-emitting diode structure formed on said spacer layer, said light-emitting diode structure comprising: (1) one or more lower carrier confinement layers, (2) one or more upper carrier confinement layers, and (3) one or more light-emitting active layers formed between the lower and upper carrier confinement layers, wherein the lower and upper carrier layers respectively comprise GaN-based materials doped with opposite types of dopant species and are in electrical contact with opposite electrodes, and wherein the one or more light-emitting active layers comprise undoped GaN-based materials.

14. The light-emitting diode assembly of claim 13, wherein both said free-standing GaN substrate and said spacer layer are doped with n-type dopant species, wherein the lower carrier confinement layers comprise n-doped GaN-based materials and are in electrical contact with an n-electrode through said free-standing GaN substrate and said spacer layer, and wherein the upper carrier confinement layers comprise p-doped GaN-based materials and are in electrical contact with a p-electrode.

15. The light-emitting diode assembly of claim 13, wherein both said free-standing GaN substrate and said spacer layer are undoped, wherein the lower carrier confinement layers comprise n-doped GaN-based materials and are in electrical contact with an n-electrode, and wherein the upper carrier confinement layers comprise p-doped GaN-based materials and are in electrical contact with a p-electrode.

16. The light-emitting diode assembly of claim 13, wherein both said free-standing GaN substrate and said spacer layer are doped with p-type dopant species, wherein the lower carrier confinement layers comprise p-doped GaN-based materials and are in electrical contact with a p-electrode through said free-standing GaN substrate and said spacer layer, and wherein the upper carrier confinement layers comprise n-doped GaN-based materials and are in electrical contact with an n-electrode.

17. The light-emitting diode assembly of claim 13, wherein both said free-standing GaN substrate and said spacer layer are undoped, wherein the lower carrier confinement layers comprise p-doped GaN-based materials and are in electrical contact with a p-electrode, and wherein the upper carrier confinement layers comprise n-doped GaN-based materials and are in electrical contact with an n-electrode.

18. The light-emitting diode assembly of claim 13, wherein conductivity of the spacer layer is substantially similar to that of the free-standing GaN substrate.

19. The light-emitting diode assembly of claim 18, wherein the spacer layer and the free-standing GaN substrate define an interfacial region therebetween, which has a high impurity concentration in relation to remaining regions of said spacer layer and said GaN substrate.

20. The light-emitting diode assembly of claim 13, wherein the spacer layer is doped with an n-type dopant species at a concentration ranging from about 2×10¹⁷ to about 5×10¹⁸ atoms/cc.

21. The light-emitting diode assembly of claim 13, wherein the light-emitting active layers comprise single or multiple quantum wells.

22. The light-emitting diode assembly of claim 13, wherein a barrier layer is provided between the upper carrier confinement layers and the light-emitting active layers, said barrier layer being formed of a material comprising AlGaN containing at least 50% Al by weight, based on the total weight of Al and Ga therein.

23. The light-emitting diode assembly of claim 13, wherein said GaN-based light-emitting diode structure comprises a UV LED.

24. The light-emitting diode assembly of claim 13, wherein said GaN-based light-emitting diode structure comprises a blue or green LED.

25. The light-emitting diode assembly of claim 13, wherein the spacer layer has a thickness in a range of from 0.5 μm to 2.0 μm.

26. The light-emitting diode assembly of claim 13, wherein the spacer layer has a thickness in a range of from 0.5 μm to 1.5 μm.

27. The light-emitting diode assembly of claim 13, wherein the spacer layer has a thickness in a range of from 0.5 μm to 1.0 μm.

29. The light-emitting diode assembly of claim 13, wherein the spacer layer has a thickness in a range of from 1.0 μm to 1.5 μm.
